(19) United States
(12) Patent Application Publication
(10) Pub. No.: US 2025/0054901 A1
(43) Pub. Date: Feb. 13, 2025

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Seiichi TAKAHASHI, Matsumoto-city (JP)

(73) Assignee: FUJI ELECTRIC CO., LTD., Kawasaki-shi (JP)

(21) Appl. No.: 18/754,602

(22) Filed: Jun. 26, 2024

(30) Foreign Application Priority Data
Aug. 9, 2023 (JP) 2023-130092

(51) Int. Cl. H01L 23/00; H01L 23/31; H01L 23/498

(52) U.S. Cl. CPC H01L 24/48; H01L 23/3121; H01L 23/49811; H01L 24/49; H01L 2224/48225; H01L 2224/49175; H01L 2924/1511

(57) ABSTRACT

A semiconductor device includes an insulating substrate having a plurality of wiring patterns thereon, a semiconductor chip disposed on one wiring pattern among the plurality of wiring patterns, metal wiring electrically connected to the semiconductor chip, a case having a bottom at which the insulating substrate is disposed, and an insulating encapsulating member that fills in the case from an upper surface of the insulating substrate to have a thickness sufficient to cover the semiconductor chip while leaving at least part of the metal wiring exposed.

### CROSS-REFERENCE TO RELATED APPLICATION

This application is based upon and claims the benefit of priority of the prior Japanese Patent Application No. 2023-130092, filed on Aug. 9, 2023, the entire contents of which are incorporated herein by reference.

### BACKGROUND OF THE INVENTION

### 1. Field of the Invention

The embodiment discussed herein relates to a semiconductor device and a method of manufacturing a semiconductor device.

### 2. Background of the Related Art

A semiconductor device is constructed with an insulating circuit board, on which a power semiconductor element has been mounted, bonded to a heat dissipating base, and is electrically connected to an external circuit via metal terminals. The semiconductor device includes a resin case that forms an enclosed space, the inside of which is filled with an insulating encapsulating member.

As one example of a related technology is a semiconductor power module disclosed in Japanese Laid-open Patent Publication No. 2001-210758. This module is constructed so that a member with an opening only at the bottom side thereof is formed in a case that supports a substrate, with the bottom side of the member contacting a primary encapsulating resin to form a closed space inside.

### SUMMARY OF THE INVENTION

According to an aspect of the present disclosure, there is provided a semiconductor device, including: an insulating substrate having a plurality of wiring patterns disposed thereon; a semiconductor chip disposed on one wiring pattern among the plurality of wiring patterns; metal wiring electrically connected to the semiconductor chip; a case having a bottom at which the insulating substrate is disposed; and an insulating encapsulating member that fills in the case to have a thickness from an upper surface of the insulating substrate in a direction orthogonal to a surface of the insulating substrate sufficient to cover the semiconductor chip while leaving at least part of the metal wiring exposed therefrom.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 depicts one example of a semiconductor device according to the present embodiment;

FIG. 2 depicts the relationship between the depth of an insulating encapsulating member and the generation of bubbles;

FIG. 3 depicts an example configuration of a semiconductor device;

FIG. 4 depicts an example method of manufacturing a semiconductor device;

FIG. 5 depicts an example operation of covering with an insulating member;

FIG. 6 depicts an example of a method of manufacturing a semiconductor device;

FIG. 7 depicts an example method of manufacturing a semiconductor device;

FIG. 8 depicts an example method of manufacturing a semiconductor device;

FIG. 9 depicts an example equivalent circuit of a semiconductor device;

FIG. 10 is a plan view of a metal-oxide-semiconductor field-effect transistor (MOSFET);

FIG. 11 depicts an example where a terminal that extends to the outside and wires are covered with insulating members;

FIGS. 12A and 12B depict one example of filling with an insulating encapsulating member and covering with insulating members, where FIG. 12A depicts filling with an insulating encapsulating member and covering of a terminal that extends to the outside and FIG. 12B depicts filling with an insulating encapsulating member and covering of a wire;

FIG. 13 depicts an example where a terminal that extends to the outside and wires are covered with insulating members;

FIG. 14 is a cross-sectional view of a part taken along a line X1-X2 indicated in FIG. 13;

FIGS. 15A and 15B depict one example of filling with an insulating encapsulating member and covering with insulating members, where FIG. 15A depicts filling with an insulating encapsulating member and covering of a terminal that extends to the outside and FIG. 15B depicts filling with an insulating encapsulating member and covering of wires;

FIG. 16 depicts an example where a first terminal and a second terminal are covered with insulating members;

FIGS. 17A and 17B depict one example of filling with an insulating encapsulating member and covering with an insulating member, where FIG. 17A depicts filling with an insulating encapsulating member and covering of a second terminal, and FIG. 17B depicts filling with an insulating encapsulating member and covering of a first terminal;

FIG. 18 depicts one example of where control electrode wiring and rear surface electrode wiring are covered with insulating members;

FIG. 19 depicts one example of where front surface main electrode wiring and rear surface electrode wiring are covered with insulating members;

FIG. 20 depicts an example configuration of a semiconductor device equipped with a vertical semiconductor chip; and

FIG. 21 depicts an example configuration of a semiconductor device equipped with a vertical semiconductor chip.

### DETAILED DESCRIPTION OF THE INVENTION

An embodiment will be described below with reference to the accompanying drawings.

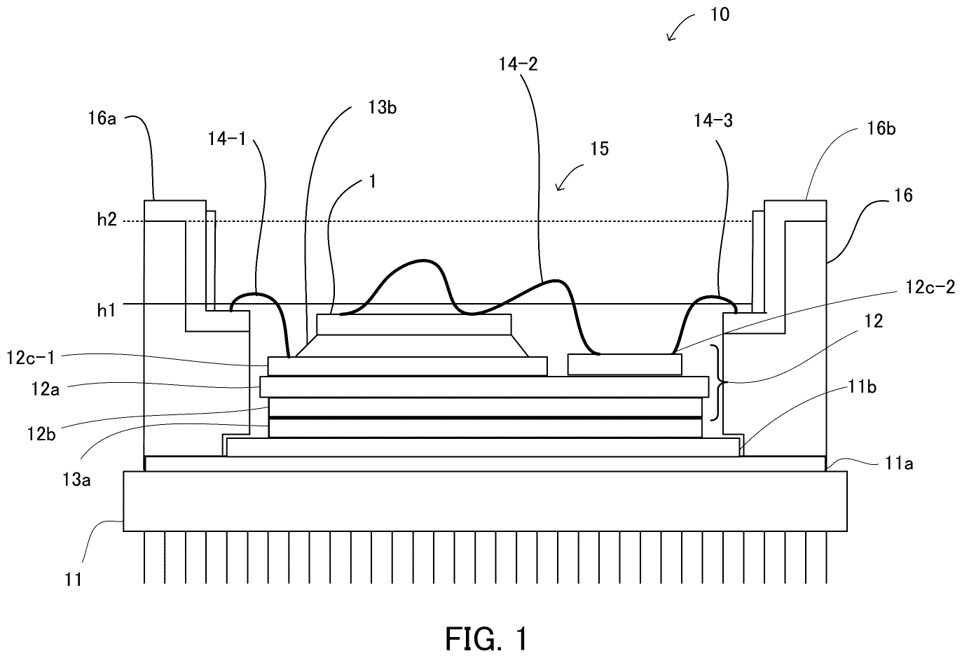

FIG. 1 depicts one example of a semiconductor device according to the present embodiment. FIG. 1 depicts a horizontal section of a semiconductor device 10. The semiconductor device 10 includes a semiconductor chip 1 and an insulating substrate (or “insulating circuit board”) 12 that are mounted on a cooler 11.

The insulating substrate 12 includes a ceramic 12a and patterns (foil) 12b, 12c-1, and 12c-2 (hereinafter, the patterns 12c-1 and 12c-2 are collectively referred to as the “patterns 12c”). When the patterns 12b and 12c are copper patterns for example, a direct copper bonding (DCB) substrate, where the patterns 12b and 12c are directly bonded to the ceramic 12a, may be used.

A metal base plate (or “heat dissipating base”) 11b is mounted via heat dissipating grease (or “thermal grease”) 11a onto the upper surface of the cooler 11 so that one surface of the metal base plate 11b faces the cooler 11 and the insulating substrate 12 is mounted on the other surface of the metal base plate 11b. The pattern 12b of the insulating substrate 12 is bonded via solder 13a to the metal base plate 11b. A semiconductor chip 1 made of silicon, for example, is bonded via solder 13b onto the pattern 12c-1 of the insulating substrate 12.

On the other hand, metal wires (hereinafter referred to simply as the “wires”) 14-1, 14-2, and 14-3 which are “metal wiring” are for example bonding wires that have a wire diameter of 300 μm to 500 μm and are made of aluminum. The wire 14-1 connects the pattern 12c-1 and an external terminal 16a provided on a case 16. The material of the wires may be copper, silver, gold, or the like.

The wire 14-2 connects an electrode of the semiconductor chip 1 and the pattern 12c-2, which is a lead electrode on the insulating substrate 12. Note that as one example, an electrode (or Al—Si electrode) that has been covered with an Al—Si alloy film may be formed on the semiconductor chip 1.

The wire 14-3 joins the pattern 12c-2 and an external terminal 16b provided on the case 16. These wires 14-1, 14-2, and 14-3 are attached by wire bonding using ultrasonic waves and a load. Note that aside from wires, a lead frame made of a metal plate or conductive pins may be used as the metal wiring connected to the semiconductor chip 1. Such wiring may be made of a metal material, such as copper, and may be connected to the semiconductor chip 1 via solder or sintered material.

The insulating substrate 12 to which the semiconductor chip 1 is bonded is housed in the case 16, and a region surrounded by the case 16 and the metal base plate 11b is filled with an insulating encapsulating member 15 to encapsulate the device. Note that the case 16 and the metal base plate 11b are attached using adhesive or the like.

Here, the patterns 12b and 12c of the insulating substrate 12 are made of a material with superior electrical conductivity. Examples of such material include copper, aluminum, and an alloy containing at least one of these metals. The thickness of the patterns 12b and 12c is preferably 0.10 mm or more and 2.00 mm or less, and more preferably 0.20 mm or more and 1.00 mm or less.

In addition to the semiconductor chip 1, wiring members, such as bonding wires, lead frames, and connection terminals, and electronic components may be appropriately disposed as appropriate on the patterns 12c.

It is also possible to perform a plating treatment on the patterns 12c using a material with superior corrosion resistance. Example materials include aluminum, nickel, titanium, chromium, molybdenum, tantalum, niobium, tungsten, vanadium, bismuth, zirconium, hafnium, gold, silver, platinum, palladium, and an alloy containing at least one of these metals. Note that the number, disposed positions, and shapes of the patterns 12c may be appropriately selected in keeping with the device design.

On the other hand, the metal base plate 11b is made of metal with superior thermal conductivity. Example metals include aluminum, iron, silver, copper, and an alloy containing at least one of these metals. Example alloys include metal composites such as aluminum-silicon nitride (Al—SiC) and magnesium-silicon nitride (Mg—SiC).

To improve corrosion resistance, a material such as nickel may be formed by plating or the like on the surface of the metal base plate 11b. In more detail, aside from nickel, nickel-phosphorus alloy, nickel-boron alloy, or the like may be used. The thickness of the plating film is preferably 1 μm or more, and more preferably 5 μm or more. The cooler 11 is a heat sink with one or more fins, a cooling device that uses water cooling, or the like.

On the other hand, the semiconductor chip 1 is a power device made of silicon, silicon carbide, or gallium nitride. The semiconductor chip 1 includes a switching element. The switching element is a power metal-oxide-semiconductor field-effect transistor (MOSFET), an insulated gate bipolar transistor (IGBT), or the like.

This semiconductor chip 1 includes for example a drain electrode (or positive electrode, or the collector electrode of an IGBT) and a source electrode (or negative electrode, or the emitter electrode of an IGBT) as main electrodes, and a gate electrode as a control electrode.

The semiconductor chip 1 includes a diode element. As examples, the diode element is a freewheeling diode (FWD), such as a Schottky Barrier Diode (SBD) or a PiN (P-intrinsic-N) diode.

The thickness of the semiconductor chip 1 is for example 80 μm or more and 500 μm or less, with an average thickness of around 200 μm. Note that other electronic components may also be disposed on the patterns 12c as appropriate. Examples of such electronic components include a capacitor, a resistor, a thermistor, a current sensor, and a control integrated circuit.

On the other hand, in the region surrounded by the insulating substrate 12 and the case 16, the insulating encapsulating member 15 covers all or part of the semiconductor chip 1 from the upper surface of the insulating substrate 12 and fills this region to a depth where the wires 14-1, 14-2, and 14-3 are at least partially exposed.

As one example, in the past, the filling height (or “filling thickness”) h2 of the insulating encapsulating member 15 was approximately 15 mm from the upper surface of the insulating substrate 12 (in the example in FIG. 1, the upper surfaces of the patterns 12c-1 and 12c-2). On the other hand, in the semiconductor device 10 according to the present embodiment, the filling height h1 of the insulating encapsulating member 15 is 3 mm or less from the upper surface of the insulating substrate 12. Note that gel is used for the insulating encapsulating member 15, and as examples, silicone gel or resin with favorable shape conformability may be used as the gel.

In this way, the semiconductor device 10 includes, in the region surrounded by the insulating substrate 12 and the case 16, the insulating encapsulating member 15 that fills the region from the upper surface of the insulating substrate 12 to a depth where the semiconductor chip 1 is covered and at least part of the wires 14-1 and 14-2 are exposed. The bonded parts of the semiconductor chip 1 and the wire 14-2 are also covered with the insulating encapsulating member 15.

By using this configuration, in the semiconductor device 10, it is possible to prevent the generation of bubbles, peeling, and condensation in the insulating encapsulating member, which improves the insulation reliability. Note that the semiconductor device 10 to which the above configuration has been applied is effective as a semiconductor device that has a small capacity and a general-purpose voltage rating for example.

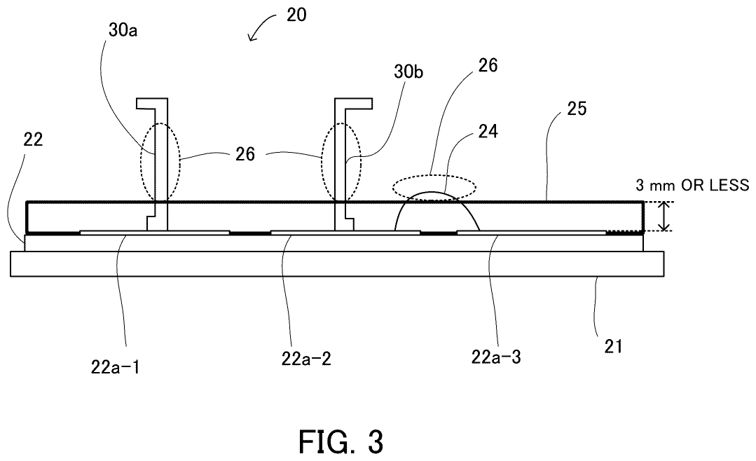

On the other hand, for a semiconductor device with a large capacity and a high voltage rating, it is important to ensure that terminals and the like are favorably insulated from each other, even when the filling height of the insulating encapsulating member is 3 mm or less from the upper surface of the insulating substrate. This means that for a semiconductor device with a large capacity and a high voltage rating, it is important to not only lower the filling height of the insulating encapsulating member but also to cover parts of the terminals and wires exposed from the insulating encapsulating member with an insulating member to achieve favorable insulation for such parts. A large-capacity, high-voltage rated semiconductor device configured so that parts of terminals, wires, and the like are covered with insulating members will be described later with reference to FIG. 3 onward.

### Insulating Encapsulating Member

Silicone gel or resin is used for the insulating encapsulating member that fills the inside of the semiconductor device. Silicone gel that has favorable shape conformability is most commonly used. In recent years, resin-encapsulated structures have been used in applications (mainly in-vehicle applications) with demands regarding heat resistance and heat-cycle resistance.

The insulating encapsulating member provides mechanical protection to the internal circuits of a semiconductor device (that is, protection from foreign matter and the like) and also provides insulation between electrodes (or between circuits). Insulation reliability is ensured by covering and filling semiconductor element surfaces, wire surfaces, circuit surfaces including terminal surfaces, and spaces between electrodes (that is, between circuits) with an insulating material.

As one example, when foreign matter that is electrically conductive adheres between two exposed circuits, the circuits may become shorted and fail. Even foreign matter with low conductivity may cause shorting-based failures due to tracking. This means that by covering and filling the circuit surfaces including the semiconductor element surfaces, wire surfaces, and terminal surfaces with the insulating encapsulating member, it is possible to protect the circuits, which prevents failures. By also covering and filling the spaces between the electrodes with an insulating encapsulating member, it is possible to make insulation distances much shorter than when insulating with air, which makes it possible to miniaturize semiconductor modules through high-density packaging.

### Problems Due to Generation of Bubbles in Insulating Encapsulating Member

Silicone gel is soft and has high conformability, which makes it resistant to peeling, but is highly hygroscopic (that is, has high moisture permeability), which creates a tendency for air bubbles and condensation to occur inside the gel. It is possible to suppress the generation of bubbles by hardening the gel, but this causes a drop in conformability and makes it easier for the gel to peel off.

Since resin is highly elastic (due to its hardness), bubbles are not produced during use. However, resin is more susceptible to peeling than gel. As described above, when generation of bubbles, peeling, and/or condensation occur for an insulating material, the reliability of the electrical insulation will fall.

Here, since insulating encapsulating members such as silicone gel and resin have a higher dielectric constant than air, when voids are produced due to air bubbles inside the insulating encapsulating member between electrodes or peeling of the insulating encapsulating member, the electric field strength will increase at the voids and the insulation reliability will fall. As one example, when voids are produced, the discharge starting voltage will fall to about one third. In particular, since the electric field tends to be concentrated at the surface of a bonding wire, the discharge starting voltage will fall to around one sixth compared to other areas, and the insulation performance will fall further as the bonding wire is made thinner.

If the maximum rated voltage of a semiconductor chip is around 1.7 kV or lower, even when voids are produced between electrodes, the minimum insulation distances from the bonding wires will be relatively small, which places little constraint on design freedom (miniaturization). However, when the maximum rated voltage of a semiconductor chip is a high withstand voltage of 3.3 kV or higher, the minimum insulation distance for bonding wires with a diameter of around 300 μm is larger than the minimum insulation distance for bonding wires with a diameter of around 125 μm used when the maximum rated voltage is around 1.7 kV or lower, which hinders miniaturization.

The present embodiment has been conceived in view of the issues described here, and are intended to improve insulation reliability by preventing the generation of bubbles, peeling, and condensation for an insulating encapsulating member.

### Depth of Insulating Encapsulating Member

When silicone gel that has absorbed moisture heats up, bubbles are produced inside the silicone gel (in particular at interfaces between the silicone gel and other members). This is because moisture that fails to completely dissolve due to the heat increases the internal pressure of bubble nuclei (which are microscopic spaces and defects) and causes swelling.

This phenomenon competes with the rate at which moisture escapes from the upper surface of the gel when the temperature rises. This means that even when a hygroscopic gel is heated, so long as the concentration of moisture in the gel falls before the internal pressure of the bubble nuclei has sufficiently risen, bubbles will not be produced.

On the other hand, when silicone gel that has absorbed moisture cools down, the absorbed moisture will become aggregated within the gel and condense. This is because the amount of water vapor (gas) that may exist in gaps within the gel decreases, with this phenomenon also competing with the rate at which moisture escapes from the upper surface of the gel. So long as the moisture concentration in the gel falls before the relative humidity of gaps within the gel reaches 100%, condensation will not occur.

Since moisture is transported inside the gel due to diffusive transport, the moisture desorption rate is inversely proportional to the square of the thickness (that is, when the thickness is reduced from 15 mm to 3 mm, the moisture desorption rate becomes twenty-five times faster). Accordingly, by reducing the thickness of the silicone gel, which serves as the insulating encapsulating member, to a predetermined depth, it is possible to improve the moisture desorption rate and suppress both the generation of bubbles and the occurrence of condensation.

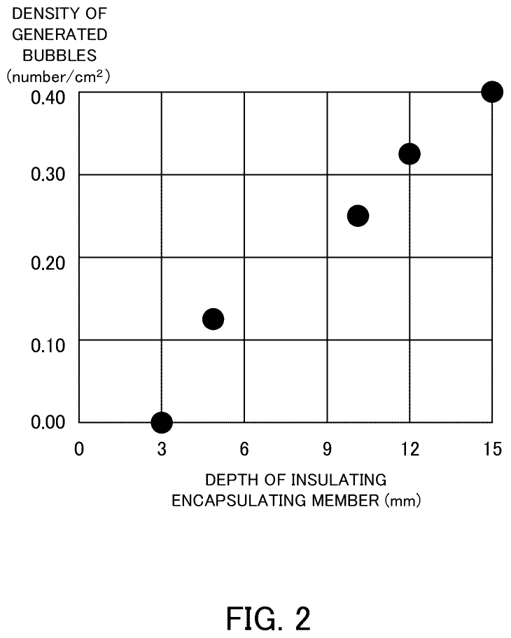

FIG. 2 depicts the relationship between the depth of the insulating encapsulating member and the generation of bubbles. The vertical axis indicates the density of generated bubbles (in bubbles/cm²), and the horizontal axis indicates the depth (in mm) of the insulating encapsulating member. The graph depicts the generated number of bubbles measured after the insulating encapsulating member was left on a hot plate at 150° C. after first absorbing moisture for 24 hours at 85° C. and 85% humidity. As depicted in FIG. 2, there is a positive correlation between bubbles and the depth of the insulating encapsulating member, and no bubbles are observed when the insulating encapsulating member is 3 mm deep.

According to the present embodiment, by setting the depth (thickness) of the insulating encapsulating member at 3 mm or less to increase the speed at which the insulating encapsulating member dries, the occurrence of bubbles and condensation are suppressed, even when a hygroscopic gel is heated and cooled.

### Large-Capacity, High-Voltage Rated Semiconductor Device

Next, a semiconductor device and a method of manufacturing a semiconductor device according to the present embodiment will be described in detail below. FIG. 3 depicts an example configuration of a semiconductor device. FIG. 3 is a schematic view of a horizontal section that is useful in explaining the features of the present embodiment. As one example, a semiconductor device 20 is a large-capacity, high-voltage rated semiconductor device with a current rating of 100 A or higher and a voltage rating of 1700 V or higher.

In the semiconductor device 20, an insulating substrate 22 is mounted on one surface of a metal base plate 21, and patterns 22a-1, 22a-2, and 22a-3 are laid out on an upper surface of the insulating substrate 22. The semiconductor device 20 also includes terminals 30a and 30b that extend to the outside, with the terminal 30a being connected to the pattern 22a-1 and the terminal 30b being connected to the pattern 22a-2. In addition, the pattern 22a-2 and the pattern 22a-3 are electrically connected via a wire 24.

In this configuration, a region surrounded by the insulating substrate 22 and a case (not illustrated) is filled with an insulating encapsulating member 25 to a height of 3 mm or less from an upper surface of the insulating substrate 22. Parts of the terminals 30a and 30b that are exposed from the insulating encapsulating member 25 and a part of the wire 24 that is exposed from the insulating encapsulating member 25 are covered with insulating members 26.

As examples, adhesive or resin is used for the insulating members 26. Example resins include polyphenylene sulfide (PPS), polybutylene terephthalate (PBT), polyamide, liquid crystal polymer (LCP), polyoxymethylene (POM), polyimide, polyamide imide, polyester, epoxy resin, fluororesin, acrylic resin, silicone resin, polyolefin, and polyetherimide.

In this way, the semiconductor device 20, which has a large capacity and a high voltage rating, is configured so that the filling height of the insulating encapsulating member is set to 3 mm or lower from the upper surface of the insulating substrate and parts of the terminals and metal wires exposed from the insulating encapsulating member are covered with insulating members.

By doing so, in addition to suppressing the generation of bubbles in the insulating encapsulating member, it is also possible to ensure favorable insulation between the terminals and the like. Note that although the example in FIG. 3 depicts a state where all locations that are exposed from the insulating encapsulating member are covered with an insulating member, it is possible to cover exposed locations with an insulating member according to necessity for insulation purposes.

### Method of Manufacturing Semiconductor Device

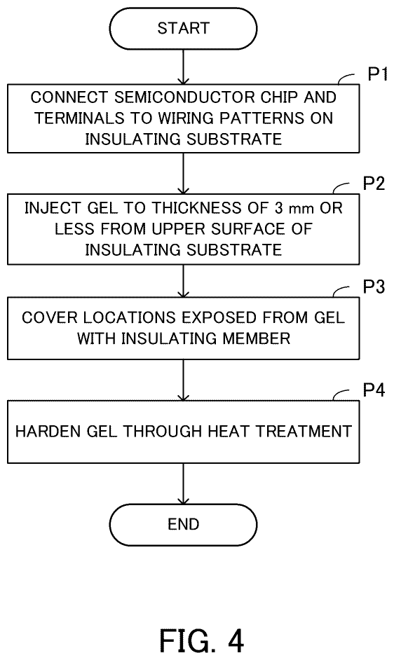

Next, a method of manufacturing a semiconductor device will be described using FIGS. 4 to 8. In the following description, the insulating encapsulating member may be referred to as “gel”. Note that when filling with gel is performed, the gel is injected and filled at locations where a high voltage of a similar level to the rated voltage is applied so as to bury areas where the insulation spatial distances are insufficient. In addition, the locations that are to be covered with an insulating member are locations that are exposed by the gel and where favorable insulation is to be ensured.

FIG. 4 depicts an example method of manufacturing a semiconductor device.

[Process P1]A semiconductor chip and terminals are connected to wiring patterns on an insulating substrate.

[Process P2] Gel is injected to fill a region, which is surrounded by the insulating substrate and a case whose bottom portion is disposed on the insulating substrate, to a thickness of 3 mm or less from the upper surface of the insulating substrate.

[Process P3] After the region has been filled with gel, locations, such as terminals and wires exposed from the gel, where insulation is to be ensured are covered with an insulating member.

[Process P4] The gel is hardened by a heat treatment.

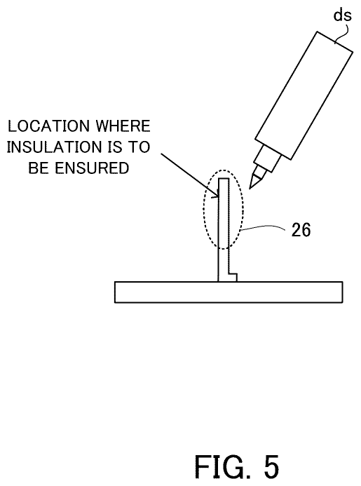

FIG. 5 depicts an example operation of covering with an insulating member. When covering a predetermined location with an insulating member, a dispenser ds may be used. Using the dispenser ds, it is possible for example to cover regions where the insulating spatial distance is insufficient, out of locations to which a high voltage of a similar level to the rated voltage is applied, with an insulating member 26.

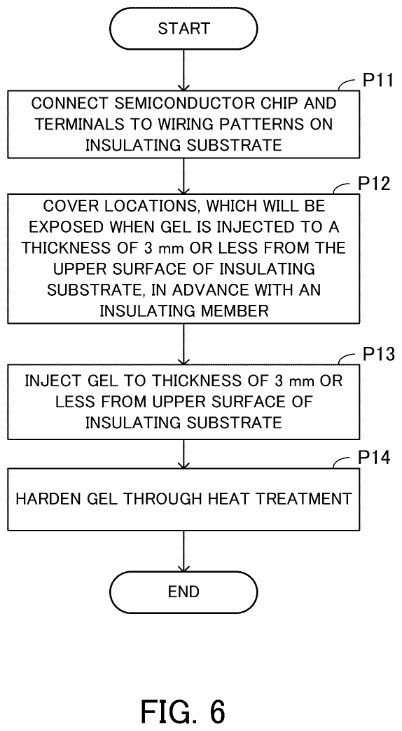

FIG. 6 depicts an example of a method of manufacturing a semiconductor device.

[Process P11]A semiconductor chip and terminals are connected to wiring patterns on an insulating substrate.

[Process P12] Locations that will be exposed when gel is injected into a region, which is surrounded by the insulating substrate and the case whose bottom portion is disposed on the insulating substrate, to a thickness of 3 mm or less from the upper surface of the insulating substrate are covered in advance with an insulating member.

[Process P13] Gel is injected into the region described above so that the region becomes filled with gel to a thickness of 3 mm or less from the upper surface of the insulating substrate.

[Process P14] The gel is hardened by a heat treatment.

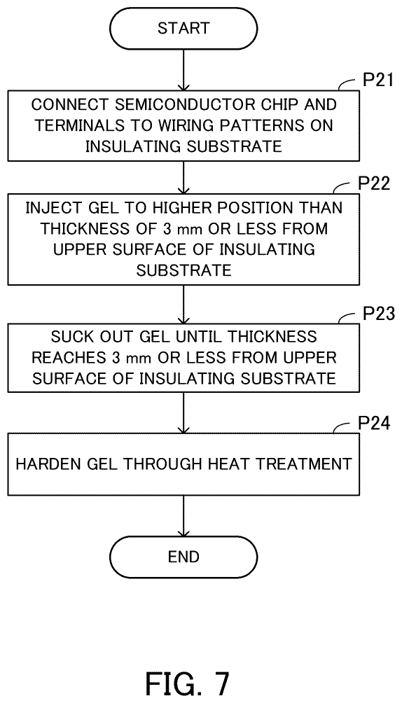

FIG. 7 depicts an example method of manufacturing a semiconductor device.

[Process P21]A semiconductor chip and terminals are connected to wiring patterns on an insulating substrate.

[Process P22] Gel is injected to fill a region surrounded by the insulating substrate and a case whose bottom portion is disposed on the insulating substrate to a higher position than a thickness of 3 mm or less from the upper surface of the insulating substrate with the gel.

[Process P23] The gel is sucked out until it reaches a thickness of 3 mm or less from the upper surface of the insulating substrate. After the gel has been sucked out, gel will remain on, which is to say gel will cover, parts, such as terminals and wires, which are exposed from the gel that has been filled to a thickness of 3 mm or less from the upper surface of the insulating substrate and where insulation is to be ensured.

[Process P24] The gel is hardened by a heat treatment.

In this way, in the method of manufacturing in FIG. 7, after the insulating encapsulating member has been injected to a position that is higher than a thickness of 3 mm or less, the insulating encapsulating member is sucked out until the thickness reaches 3 mm or less. By doing so, locations where insulation is to be ensured, such as terminals and wires, and are exposed from gel that has been filled to a thickness of 3 mm or less from the upper surface of the insulating substrate may be covered with gel without using insulating members.

Here, a suction device (or “pump”) is used to suck out the gel. Either a rotary-type or a positive displacement-type pump may be used as the suction device. A positive displacement-type pump is preferable since sucking of gel involves high viscosity, a low flow rate, and a set amount (measurement).

The sucked amount of gel is controlled by a flow meter. In the case of a rotary pump, the pump is combined with a flow meter to control the discharge amount and thereby control the depth level of the gel inside a semiconductor device. Since it is possible to quantify the discharge amount of a positive displacement pump, this characteristic may be used to control the depth level of gel inside a semiconductor device.

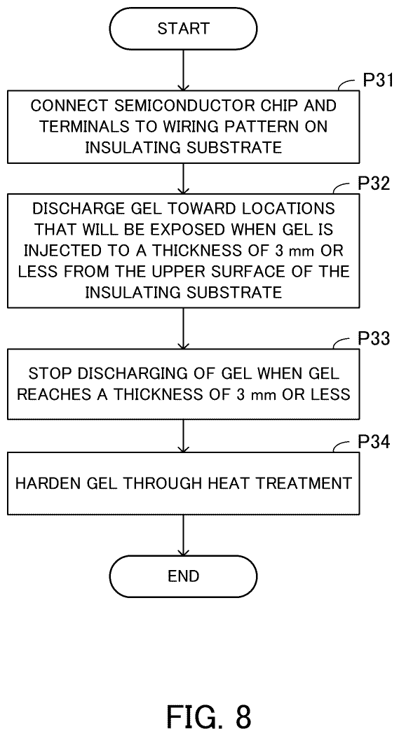

FIG. 8 depicts an example method of manufacturing a semiconductor device.

[Process P31]A semiconductor chip and terminals are connected to wiring patterns on an insulating substrate.

[Process P32] Gel is discharged towards locations, out of a region surrounded by the insulating substrate and a case whose bottom portion is disposed on the insulating substrate, that would be exposed when gel is injected to a thickness of 3 mm or less from the upper surface of the insulating substrate.

[Process P33] When the gel has reached a thickness of 3 mm or less, the discharging of gel is stopped, leaving the exposed locations described above covered with the gel.

[Process P34] The gel is hardened by a heat treatment.

In this way, with the method of manufacturing depicted in FIG. 8, gel is discharged toward locations that would be exposed when filling with gel is performed to a thickness of 3 mm or less, until a thickness of 3 mm or less is reached, and when the gel reaches a thickness of 3 mm or less, the discharging is stopped, leaving the exposed regions covered with gel.

By doing so, without using insulating members, it is possible to cover locations with gel where insulation is to be ensured, such as terminals and wires, which would otherwise be exposed from gel that has been filled to a thickness of 3 mm or less from the upper surface of the insulating substrate.

Next, examples of location to be covered with insulating members will be described. Note that in the following description, the connecting of a terminal and a pattern or the connecting of a wire and a pattern is performed using ultrasonic waves or a laser, for example.

### Equivalent Circuit of Semiconductor Device

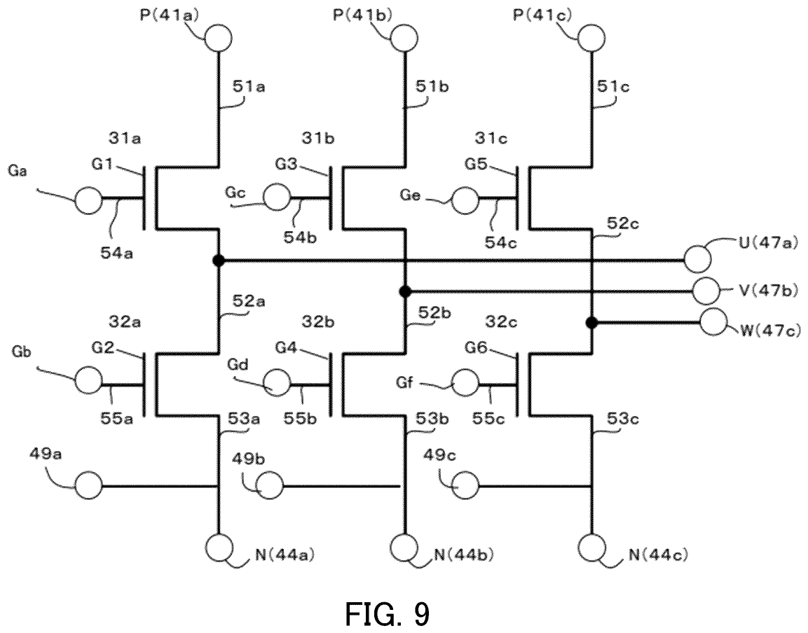

FIG. 9 depicts an example equivalent circuit of a semiconductor device. The equivalent circuit of the semiconductor device 10 is a full bridge inverter circuit that uses a MOSFET as a semiconductor chip.

Terminals 41a, 41b, and 41c, which are P terminals and extend to the outside, are electrically connected via wiring 51a, 51b, and 51c to the drain electrodes of upper-arm semiconductor chips 31a, 31b, and 31c, respectively.

A U terminal 47a, a V terminal 47b, and a W terminal 47c, which are terminals that extend to the outside, are electrically connected to junctions on wiring 52a, 52b, and 52c between the source electrodes of the upper-arm semiconductor chips 31a, 31b, and 31c and the drain electrodes of lower arm semiconductor chips 32a, 32b, and 32c, respectively.

Terminals 44a, 44b, and 44c, which are N terminals and extend to the outside are electrically connected via wiring 53a, 53b, and 53c to the source electrodes of the lower-arm semiconductor chips 32a, 32b, and 32c, respectively.

In addition, auxiliary terminals 49a, 49b, and 49c that extend to the outside are electrically connected via the wiring 53a, 53b, and 53c to the source electrodes of the lower-arm semiconductor chips 32a, 32b, and 32c and the terminals 44a, 44b, and 44c, respectively.

Control electrodes G1, G3, and G5 of the upper-arm semiconductor chips 31a, 31b, and 31c are electrically connected via wiring 54a, 54b, and 54c to control terminals Ga, Gc, and Ge that extend to the outside, and control electrodes G2, G4, and G6 of the lower-arm semiconductor chips 32a, 32b, and 32c are electrically connected via wiring 55a, 55b, and 55c to control terminals Gb, Gd, and Gf that extend to the outside.

An example where only one phase (the U phase) is disposed in the semiconductor device 10 according to the present embodiment is described below. It is obvious that it is also possible to dispose only two phases or all three phases in the semiconductor device 10.

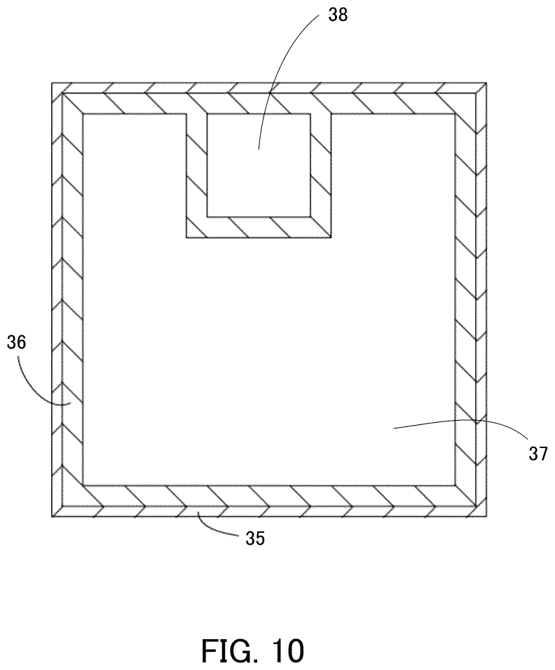

FIG. 10 is a plan view of a MOSFET. FIG. 10 is a plan view of the MOSFET with the circuit depicted in FIG. 9 and depicts the front side. The MOSFET depicted in FIG. 10 includes a semiconductor substrate 35 that is exposed at the periphery, a protective film 36 formed on the inside of the exposed semiconductor substrate 35, a source electrode 37, and a control electrode 38 which is disposed so as to separate from the source electrode 37. A drain electrode is formed on the rear surface (not illustrated).

Insulation Between Metal Wiring and Terminals that are Electrically Connected to Front Surface Electrodes and Extend to Outside

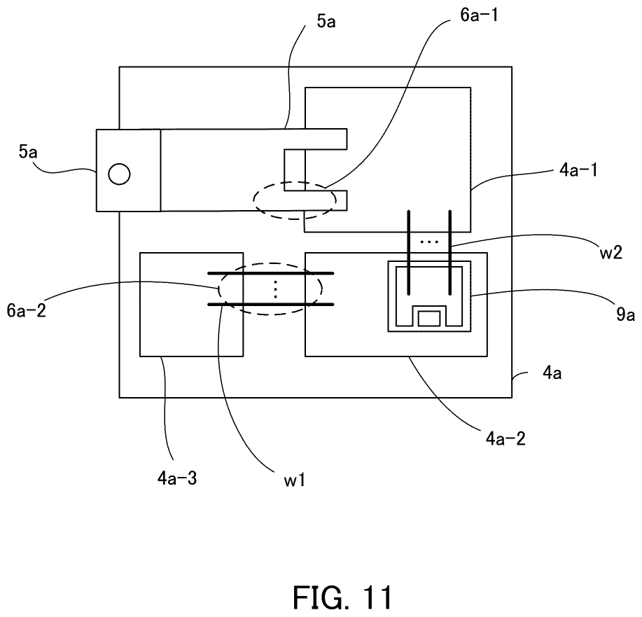

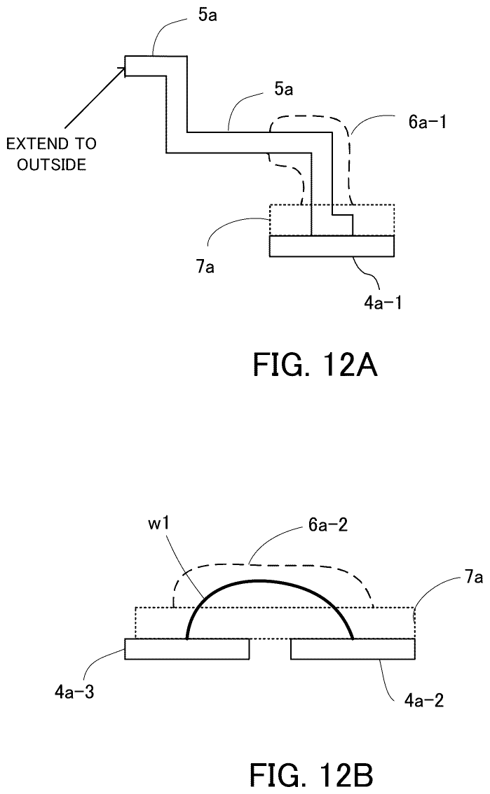

FIG. 11 depicts an example where a terminal that extends to the outside and wires are covered with insulating members. FIGS. 12A and 12B depict one example of filling with an insulating encapsulating member and covering with insulating members. FIG. 12A depicts filling with an insulating encapsulating member and covering of a terminal that extends to the outside, and FIG. 12B depicts filling with an insulating encapsulating member and covering of a wire.

In FIG. 11, patterns 4a-1, 4a-2, and 4a-3 are laid out on an insulating substrate 4a, and a vertical semiconductor chip 9a is bonded to the pattern 4a-2 by soldering or the like.

A front surface main electrode (or “source electrode”) of the semiconductor chip 9a is electrically connected to the pattern 4a-1 via a plurality of wires w2, and the terminal 5a which extends to the outside is connected to this pattern 4a-1. The wires w1 and w2 are metal wires that are electrically connected to the semiconductor chip.

A rear surface main electrode (or “drain electrode”) of the semiconductor chip 9a is connected to the pattern 4a-2. The plurality of wires w1 are connected to the pattern 4a-2 and the pattern 4a-3. Note that it is assumed that the terminal 5a, which extends to the outside, and the wires w1 are adjacent and that the insulation between these elements is to be ensured.

As one example of the correspondence between FIG. 11 and the U phase in FIG. 9, the terminal 5a corresponds to the terminal 44a, the semiconductor chip 9a corresponds to the lower arm semiconductor chip 32a, and the wires w1 correspond to the wiring 52a between the source electrode of the upper-arm semiconductor chip 31a and the drain electrode of the lower-arm semiconductor chip 32a.

In FIG. 12A, an insulating encapsulating member 7a is filled to a thickness of 3 mm or less from an upper surface of the insulating substrate 4a (that is, the upper surface of the pattern 4a-1). Also, since the terminal 5a is a location that is to be reliably insulated from the wires w1, the part of the terminal 5a that is exposed from the insulating encapsulating member 7a is covered with an insulating member 6a-1.

In FIG. 12B, the insulating encapsulating member 7a is filled to a thickness of 3 mm or less from the upper surface of the insulating substrate 4a (that is, the upper surfaces of patterns 4a-2 and 4a-3). Since the wires w1 are a location whose insulation from the terminal 5a is to be ensured, parts of the wires w1 exposed from the insulating encapsulating member 7a are covered with an insulating member 6a-2.

Note that although both the terminal 5a and the wires w1 are covered with the insulating member in the above description, only either the terminal 5a or the wires w1 may be covered with an insulating member. When the wires w2 have parts that are exposed from the insulating encapsulating member 7a, such parts may also be covered with an insulating member. It is also possible to use lead frames in place of the wires w1 and w2.

Insulation Between Wires and Terminal that is Connected to Rear Surface Electrode and Extends to Outside

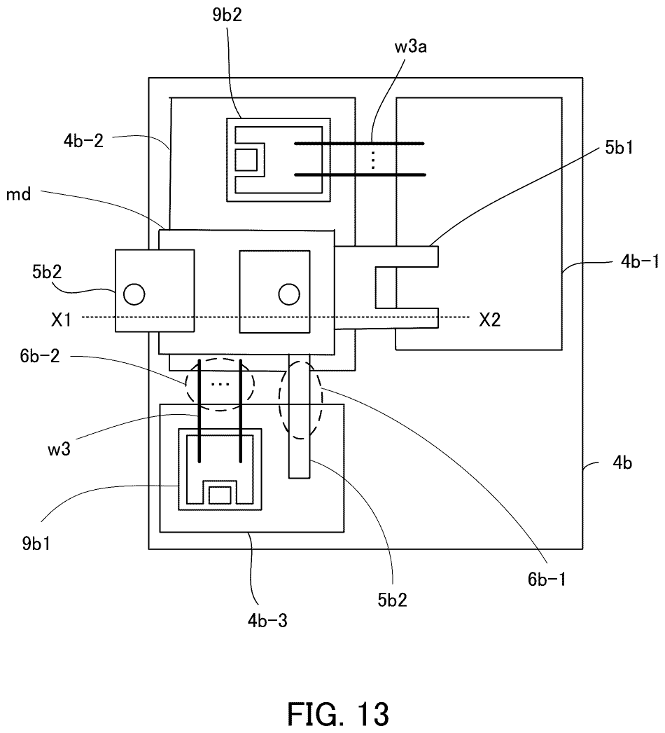

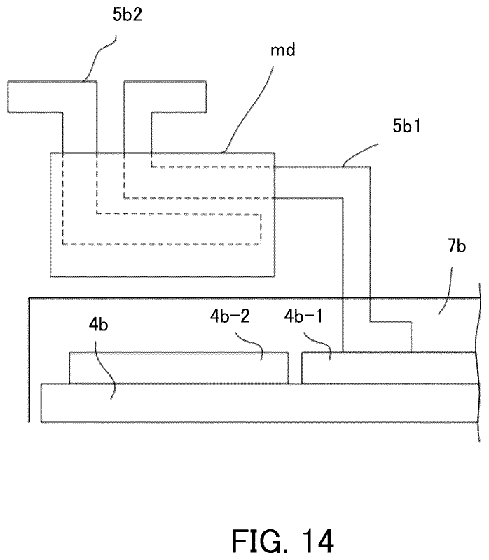

FIG. 13 depicts an example where a terminal that extends to the outside and wires are covered with insulating members, and FIG. 14 is a cross-sectional view of a part taken along a line X1-X2 indicated in FIG. 13. Patterns 4b-1, 4b-2, and 4b-3 are laid out on the insulating substrate 4b, a vertical semiconductor chip 9b1 is bonded to the pattern 4b-3 by soldering or the like, and a vertical semiconductor chip 9b2 is bonded to the pattern 4b-2 by soldering or the like.

A front surface main electrode of the semiconductor chip 9b1 is connected via a plurality of wires w3 to the pattern 4b-2. A front surface main electrode of the semiconductor chip 9b2 is connected via a plurality of wires w3a to the pattern 4b-1. The wires w3 and w3a are metal wires that are electrically connected to the semiconductor chips.

A terminal 5b1 is connected to the pattern 4b-1. A terminal 5b2 that extends to the outside is connected to the pattern 4b-3 and to the rear surface main electrode of the semiconductor chip 9b1. The terminals 5b1 and 5b2 are integrated by and insulated from each other by molded resin md. Note that it is assumed that the terminal 5b2 and the wires w3 are adjacent and correspond to a location where insulation is to be ensured.

As one example of the correspondence between FIG. 13 and the U phase in FIG. 9, the terminal 5b2 corresponds to the terminal 41a, the semiconductor chip 9b1 corresponds to the upper-arm semiconductor chip 31a, and the wires w3 and the pattern 4b-2 correspond to the wiring 52a between the source electrode of the upper-arm semiconductor chip 31a and the drain electrode of the lower-arm semiconductor chip 32a. In addition, the semiconductor chip 9b2 corresponds to the semiconductor chip 32a and the terminal 5b1 corresponds to the terminal 44a.

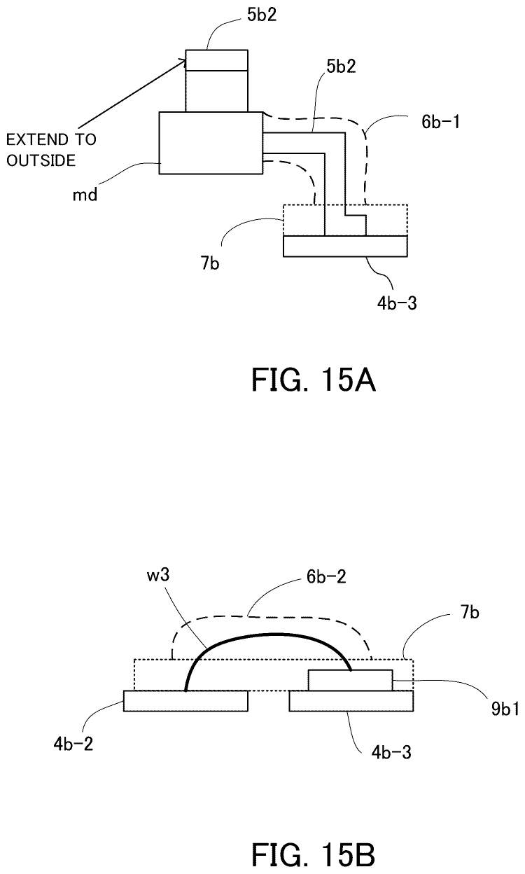

FIGS. 15A and 15B depict one example of filling with an insulating encapsulating member and covering with insulating members. FIG. 15A depicts filling with an insulating encapsulating member and covering of a terminal that extends to the outside and FIG. 15B depicts filling with an insulating encapsulating member and covering of wires.

In FIG. 15A, an insulating encapsulating member 7b is filled to a thickness of 3 mm or less from the upper surface of the insulating substrate 4b (that is, the upper surface of the pattern 4b-3). Since the terminal 5b2 is a location that is to be reliably insulated from the wires w3, the part of the terminal 5b2 that is exposed from the insulating encapsulating member 7b is covered with an insulating member 6b-1.

In FIG. 15B, the insulating encapsulating member 7b is filled to a thickness of around 3 mm or less from the upper surface of the insulating substrate 4b (that is, the upper surfaces of the patterns 4b-2 and 4b-3). In addition, since the wires w3 are a location that is to be reliably insulated from the terminal 5b2, the parts of the wires w3 exposed from the insulating encapsulating member 7b are covered with an insulating member 6b-2.

Note that although both the terminal 5b2 and the wires w3 are covered with insulating members in the above description, only either the terminal 5b2 or the wires w3 may be covered with an insulating member. When the wires w3a have parts that are exposed from the insulating encapsulating member 7b, such parts may also be covered with an insulating member. It is also possible to use lead frames in place of the wires w3 and w3a.

### Insulating Between First Terminal and Second Terminal

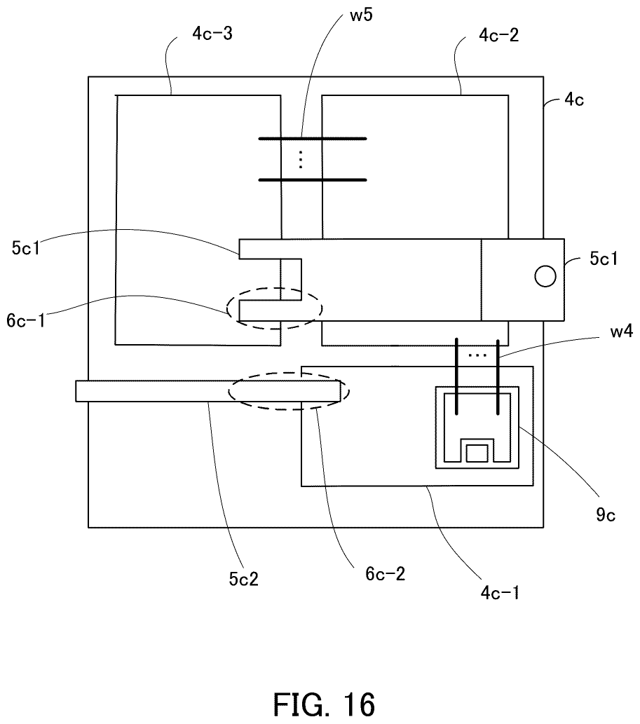

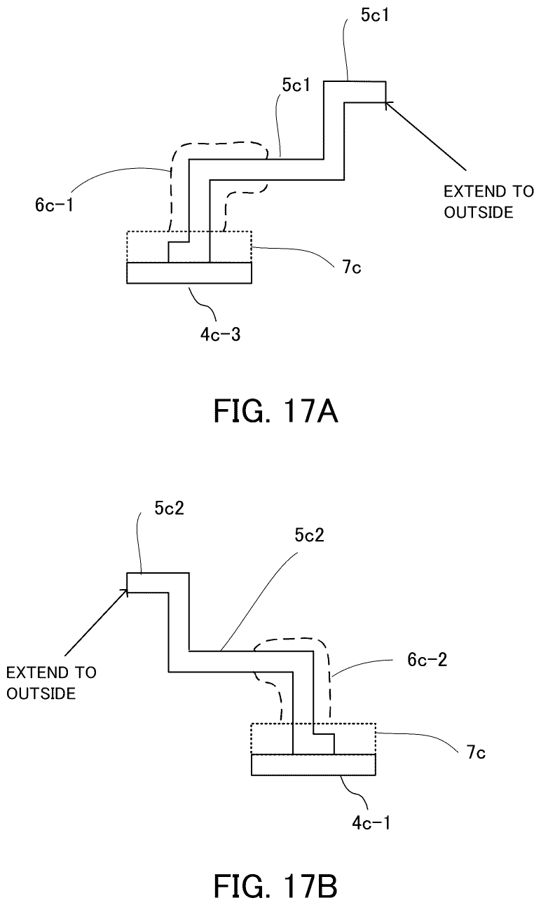

FIG. 16 depicts an example where a first terminal and a second terminal are covered with insulating members. FIGS. 17A and 17B depict one example of filling with an insulating encapsulating member and covering with an insulating member. FIG. 17A depicts filling with an insulating encapsulating member and covering of a second terminal, and FIG. 17B depicts filling with an insulating encapsulating member and covering of a first terminal.

In FIG. 16, patterns 4c-1, 4c-2, and 4c-3 are laid out on an insulating substrate 4c, and a vertical semiconductor chip 9c is bonded to the pattern 4c-1 by soldering or the like.

A front surface main electrode of the semiconductor chip 9c is electrically connected via a plurality of wires w4 to the pattern 4c-2. The wires w4 and w5 are metal wires that are electrically connected to the semiconductor chip.

The first terminal 5cl that extends to the outside is connected to the pattern 4c-3 and is electrically connected to a front surface main electrode of the semiconductor chip 9c. The second terminal 5c2 that extends to the outside is connected to the pattern 4c-1 and is electrically connected to a rear surface main electrode of the semiconductor chip 9c. Note that it is assumed that the first terminal 5cl and the second terminal 5c2 are adjacent and correspond to a location where insulation is to be ensured.

As one example of the correspondence between FIG. 16 and the U phase in FIG. 9, the second terminal 5c2 corresponds to the terminal 41a, the semiconductor chip 9c corresponds to the upper-arm semiconductor chip 31a, and the wires w4, the pattern 4c-2, wires w5, and the pattern 4c-3 correspond to the wiring 52a that is connected to the source electrode of the upper-arm semiconductor chip 31a. The first terminal 5cl corresponds to the terminal 47a.

In FIG. 17A, an insulating encapsulating member 7c is filled to a thickness of 3 mm or less from the upper surface of the insulating substrate 4c (that is, the upper surface of the pattern 4c-3). Since the first terminal 5cl corresponds to a location where insulation from the second terminal 5c2 is to be ensured, the part of the first terminal 5cl that is exposed from the insulating encapsulating member 7c is covered with an insulating member 6c-1.

In FIG. 17B, the insulating encapsulating member 7c is filled to a thickness of 3 mm or less from the upper surface of the insulating substrate 4c (that is, the upper surface of the pattern 4c-1). Since the second terminal 5c2 corresponds to a location where insulation from the first terminal 5cl is to be ensured, the part of the second terminal 5c2 that is exposed from the insulating encapsulating member 7c is covered with an insulating member 6c-2.

Note that although a configuration where both the first terminal 5cl and the second terminal 5c2 are covered with an insulating member has been described above, it is also possible to use a configuration where only one of the terminals is covered with an insulating member. Also, when the wires w4 and w5 have parts that are exposed from the insulating encapsulating member 7c, such parts may be covered with an insulating member. It is also possible to use lead frames in place of the wires w4 and w5.

### Insulation Between Control Electrode Wiring and Rear Surface Electrode Wiring

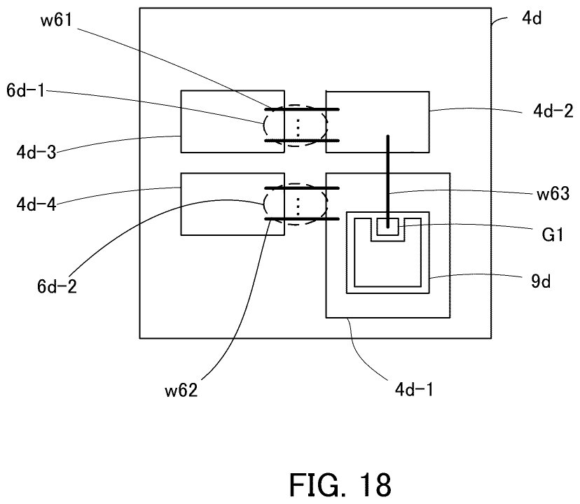

FIG. 18 depicts one example of where control electrode wiring and rear surface electrode wiring are covered with insulating members. Patterns 4d-1 to 4d-4 are laid out on the insulating substrate 4d, and a vertical semiconductor chip 9d is bonded to the pattern 4d-1 by soldering or the like.

A control electrode (gate electrode) G1 of the semiconductor chip 9d is electrically connected via a wire w63 to the pattern 4d-2, and the pattern 4d-2 is electrically connected via a plurality of wires w61 to the pattern 4d-3. The pattern 4d-4 is electrically connected via a plurality of wires w62 to the pattern 4d-1. The wires w61, w62, and w63 are metal wires that are electrically connected to the semiconductor chip.

As one example of the correspondence between FIG. 18 and the U phase in FIG. 9, the semiconductor chip 9d corresponds to the upper-arm semiconductor chip 31a, the wires w61 correspond to the wiring 54a between the control electrode G1 of the upper-arm semiconductor chip 31a and the control terminal Ga, and the wires w62 correspond to the wiring 51a between the upper arm semiconductor chip 31a and the terminal 41a.

It is assumed that the wires w61 and the wires w62 are adjacent and have parts that are exposed from the insulating encapsulating member. In this case, since the wires w61 are to be insulated from the wires w62, parts of the wires w61 that are exposed from the insulating encapsulating member are covered with an insulating member 6d-1. Likewise, since the wires w62 are to be insulated from the wires w61, parts of the wires w62 that are exposed from the insulating encapsulating member are covered with an insulating member 6d-2.

Note that although a configuration where both the wires w61 corresponding to the control electrode wiring and the wires w62 corresponding to the rear surface electrode wiring are covered with an insulating member has been described above, it is also possible to cover only either the wires w61 or the wires w62 with an insulating member. It is also possible to use lead frames in place of the wires w61 and w62.

### Insulation Between Front Surface Main Electrode Wiring and Rear Surface Electrode Wiring

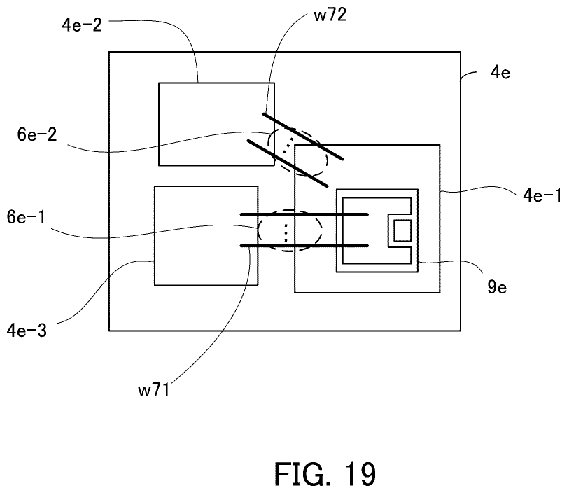

FIG. 19 depicts one example of where front surface main electrode wiring and rear surface electrode wiring are covered with insulating members. Patterns 4e-1 to 4e-3 are laid out on an insulating substrate 4e, and a vertical semiconductor chip 9e is bonded to the pattern 4e-1 by soldering or the like.

A front surface main electrode of the semiconductor chip 9e is electrically connected via a plurality of wires w71 to the pattern 4e-3. The pattern 4e-1 is connected to a rear surface main electrode of the semiconductor chip 9e, and the pattern 4e-1 is connected via a plurality of wires w72 to the pattern 4e-2. The wires w71 and w72 are metal wires that are electrically connected to the semiconductor chip.

As one example of the correspondence between FIG. 19 and the U phase in FIG. 9, the semiconductor chip 9e corresponds to the upper-arm semiconductor chip 31a, the wires w71 correspond to the wiring 52a between the upper-arm semiconductor chip 31a and the lower-arm semiconductor chip 32a, and the wires w72 correspond to the wiring 51a between the upper-arm semiconductor chip 31a and the terminal 41a.

It is assumed that the wires w71 and the wires w72 are adjacent and have parts that are exposed from the insulating encapsulating member. In this case, since the wires w71 are to be insulated from the wires w72, parts of the wires w71 that are exposed from the insulating encapsulating member are covered with an insulating member 6e-1. Likewise, since the wires w72 are to be insulated from the wires w71, parts of the wires w72 that are exposed from the insulating encapsulating member are covered with an insulating member 6e-2.

Note that although a configuration where both the wires w71 corresponding to the front surface main electrode wiring and the wires w72 corresponding to the rear surface electrode wiring are covered with an insulating member has been described above, it is also possible to cover only either the wires w71 or the wires w72 with an insulating member. It is also possible to use lead frames in place of the wires w71 and w72.

Semiconductor Device Equipped with Vertical Semiconductor Chip

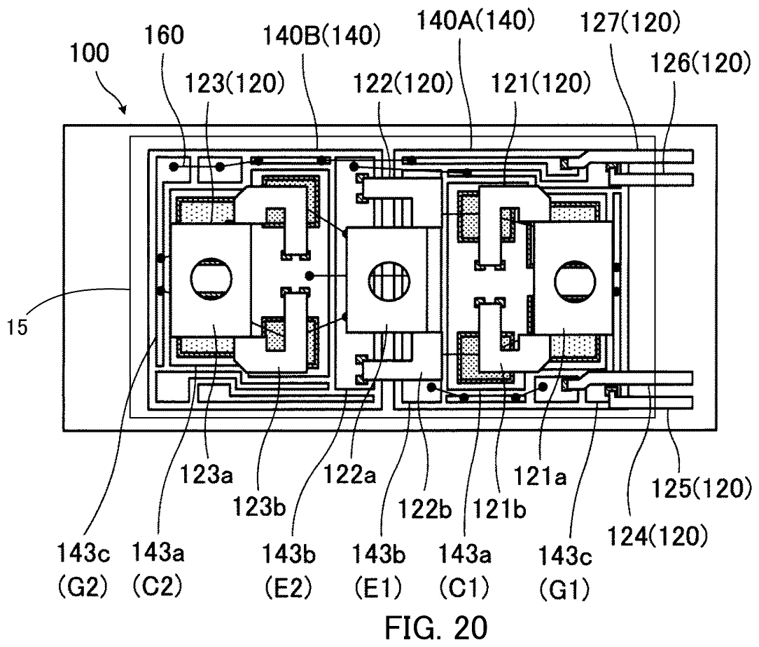

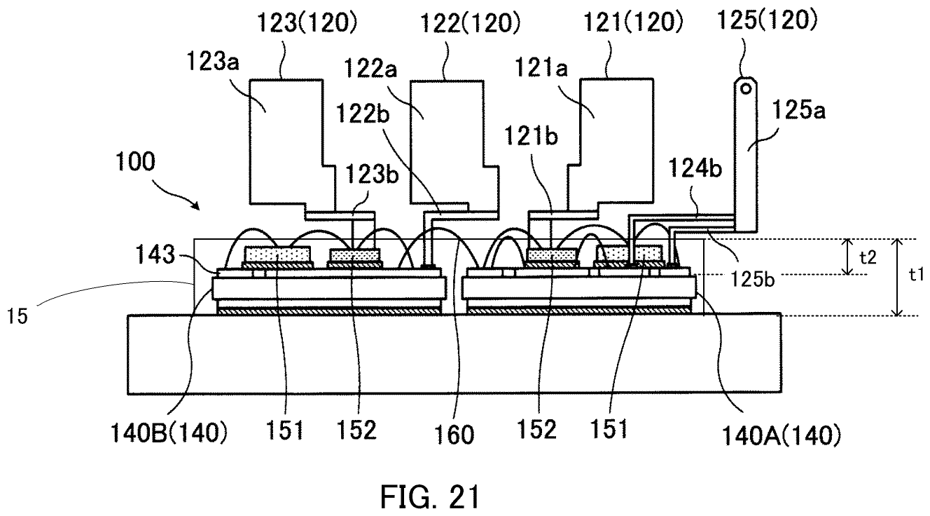

FIGS. 20 and 21 depict an example configuration of a semiconductor device equipped with a vertical semiconductor chip. FIG. 20 is a schematic plan view, and FIG. 21 is a schematic side view.

In a semiconductor device 100, three main electrode terminals 121, 122, and 123 and four auxiliary electrode terminals 124, 125, 126, and 127 are connected as electrode terminals 120. The main electrode terminals 121 to 123 and the auxiliary electrode terminals 124 to 127 are formed in advance using a metal material, such as Al or Cu, before being attached to the semiconductor device 100.

The main electrode terminal 121 is connected to a first main conductive pattern 143a (or “C1 terminal”) of a first DCB substrate 140A. The main electrode terminal 121 includes a terminal main body 121a and two legs 121b that are continuous with the terminal main body 121a. The two legs 121b of the main electrode terminal 121 are attached to the first main conductive pattern 143a of the first DCB substrate 140A by soldering or the like.

Note that the main electrode terminal 121 is provided with the two legs 121b and connected to the first main conductive pattern 143a of the first DCB substrate 140A in this way to suppress electrical bias (that is, imbalance in resistance and impedance) between one pair of an IGBT 151 and an FWD 152 on the first DCB substrate 140A and another pair of an IGBT 151 and an FWD 152.

The main electrode terminal 122 is connected to a second main conductive pattern 143b (or “E2 terminal”) of a second DCB substrate 140B. The main electrode terminal 122 includes a terminal main body 122a and two legs 122b that are continuous with the terminal main body 122a. The two legs 122b of the main electrode terminal 122 are attached to the second main conductive pattern 143b of the second DCB substrate 140B by soldering or the like.

Note that the main electrode terminal 122 is connected at two positions in this way to suppress electrical bias between one pair of an IGBT 151 and an FWD 152 on the second DCB substrate 140B and another pair of an IGBT 151 and an FWD 152.

The main electrode terminal 123 is connected to a first main conductive pattern 143a (or “E1 terminal”) of the second DCB substrate 140B, which is connected by a wire 160 to the second main conductive pattern 143b of the first DCB substrate 140A. The main electrode terminal 123 includes a terminal main body 123a and two legs 123b that are continuous with the terminal main body 123a. The two legs 123b of the main electrode terminal 123 are attached to the first main conductive pattern 143a of the second DCB substrate 140B by soldering or the like.

Note that the main electrode terminal 123 is connected at two positions in this way to suppress electrical bias between one pair of an IGBT 151 and an FWD 152 on the second DCB substrate 140B and the other pair of an IGBT 151 and an FWD 152.

The terminal main bodies 121a to 123a of the main electrode terminals 121 to 123 are substantially U-shaped with the legs 121b to 123b on the open side of the U shapes.

The auxiliary electrode terminal 124 includes a terminal main body 124a and a leg 124b. The leg 124b of the auxiliary electrode terminal 124 is attached by soldering or the like to an auxiliary conductive pattern that is electrically connected via the wire 160 to the second main conductive pattern 143b of the first DCB substrate 140A.

The auxiliary electrode terminal 125 includes a terminal main body 125a and a leg 125b. The leg 125b of the auxiliary electrode terminal 125 is attached by soldering or the like to a third main conductive pattern 143c (or “G1 terminal”) of the first DCB substrate 140A.

In the same way, the auxiliary electrode terminal 126 includes a terminal main body and a leg. The leg of the auxiliary electrode terminal 126 is attached by soldering or the like to an auxiliary conductive pattern of the first DCB substrate 140A to which the second main conductive pattern 143b (or “E2 terminal”) of the second DCB substrate 140B is electrically connected via the wire 160.

The auxiliary electrode terminal 127 includes a terminal main body and a leg. The leg of the auxiliary electrode terminal 127 is attached by soldering or the like to an auxiliary conductive pattern of the first DCB substrate 140A to which the third main conductive pattern 143c (or “G2 terminal”) of the second DCB substrate 140B is electrically connected via the wire 160.

The main electrode terminals 121 to 123 and the auxiliary electrode terminals 124 to 127 are formed in advance in shapes that enable the individual terminal main bodies to be disposed at predetermined positions within the semiconductor device 100 when the legs of the terminals have been attached at predetermined locations.

As one example, as depicted in FIG. 20, the terminals are formed in advance so that the terminal main bodies 121a to 123a of the main electrode terminals 121 to 123 are aligned at substantially equal intervals in the center of the semiconductor device 100 and the terminal main bodies of the auxiliary electrode terminals 124 to 127 are aligned along edges of the semiconductor device 100.

Although the height t1 of the insulating encapsulating member 15 that fills the space between a case (not illustrated) and the insulating substrate 140 in FIGS. 20 and 21 is relatively high compared to a height t2 of the insulating encapsulating member 15 measured from the upper surface of the insulating substrate 140, most of the planar area of the insulating encapsulating member 15 is disposed above the insulating substrate 140. Therefore, by reducing this height from the insulating substrate 140 compared to the background art, it is possible to achieve an effect of suppressing the generation of bubbles.

As described above, according to the present embodiment, it is possible to improve insulation reliability by suppressing peeling and generation of bubbles that normally occur when the temperature of hygroscopic gel rises. It is also possible to suppress condensation that occurs when the temperature of hygroscopic gel falls, and thereby achieve improved moisture resistance. It is also possible to shorten insulation distances, so that as one example, a semiconductor chip with high rated voltage of 3.3 kV is able to be designed so as to be as compact as a semiconductor chip with a general-purpose rated voltage of 1.7 kV.

It is also possible to use thin-diameter (0300 μm) wire, even in a semiconductor chip with a rated voltage of 3.3 kV, and on element surfaces, the sizes of gate pads for signal inputs only may be minimized. For high-cost silicon carbide (SiC) elements in particular, the ability to reduce the element size results in noticeable cost savings.

Although the example embodiment has been described above, the configurations of individual elements in the embodiment may be replaced with other elements with similar functions. Other freely chosen components or processes may also be added. In addition, two or more freely chosen configurations (or features) in the embodiment described above may be combined.

According to an aspect of the present disclosure, it is possible to prevent bubbles, peeling, and condensation in an insulating encapsulating member, which improves insulation reliability.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an insulating substrate having a plurality of wiring patterns disposed thereon;
a semiconductor chip disposed on one wiring pattern among the plurality of wiring patterns;
metal wiring electrically connected to the semiconductor chip;
a case having a bottom at which the insulating substrate is disposed; and
an insulating encapsulating member that fills in the case to have a thickness from an upper surface of the insulating substrate in a direction orthogonal to a surface of the insulating substrate sufficient to cover the semiconductor chip while leaving at least part of the metal wiring exposed therefrom.

2. The semiconductor device according to claim 1,
wherein the insulating encapsulating member is a gel.

3. The semiconductor device according to claim 2,
wherein the semiconductor chip is a vertical semiconductor chip including, on a front surface thereof, a front surface main electrode, and, on a rear surface thereof, a rear surface main electrode that is connected to the one wiring pattern,
wherein the metal wiring is electrically connected to the rear surface main electrode and has an exposed part not covered by, and exposed from the insulating encapsulating member, and
wherein the semiconductor device further comprises:
a first terminal, extending outside of the case and being connected to another wiring pattern among the plurality of wiring patterns, the another wiring pattern being electrically connected to the front surface main electrode, and having a part that is not covered by, and is exposed from the insulating encapsulating member; and
an insulating member covering at least part of at least one of the part of the metal wiring that is exposed from the insulating encapsulating member or the part of the first terminal that is exposed from the insulating encapsulating member.

4. The semiconductor device according to claim 3, wherein the insulating member is an adhesive or a resin.

5. The semiconductor device according to claim 3,
wherein the semiconductor chip is provided in plurality.

6. The semiconductor device according to claim 2,
wherein the semiconductor chip is a vertical semiconductor chip that includes, on a front surface thereof, a front surface main electrode, and, on a rear surface thereof, a rear surface main electrode that is connected to the one wiring pattern,
wherein the metal wiring is electrically connected to the front surface main electrode, and has a part not covered by, and being exposed from the insulating encapsulating member; and
wherein the semiconductor device further comprises:
a first terminal extending outside of the case, being connected to the one wiring pattern among the plurality of wiring patterns that is electrically connected to the rear surface main electrode, and having a part that is not covered by, and is exposed from the insulating encapsulating member, and
an insulating member covering at least part of at least one of the part of the metal wiring that is exposed from the insulating encapsulating member or the exposed part of the first terminal that is exposed from the insulating encapsulating member.

7. The semiconductor device according to claim 2,
wherein the semiconductor chip is a vertical semiconductor chip including, on a front surface thereof, a front surface main electrode, and, on a rear surface thereof, a rear surface main electrode that is connected to the one wiring pattern,
wherein the semiconductor device further comprises:
a first terminal extending outside of the case and being connected to another wiring pattern among the plurality of wiring patterns, and having a part that is not covered by, and is exposed from the insulating encapsulating member, the another wiring pattern being electrically connected to the front surface main electrode;
a second terminal extending outside of the case, being connected to yet another wiring pattern among the plurality of wiring patterns, and having a part that is not covered by, and is exposed from the insulating encapsulating member, the yet another wiring pattern being electrically connected to the rear surface main electrode; and
an insulating member that covers at least part of at least one of the part of the first terminal that is exposed from the insulating encapsulating member or the part of the second terminal that is exposed from the insulating encapsulating member.

8. The semiconductor device according to claim 7, wherein
the semiconductor chip is provided in plurality, and
the first terminal and the second terminal are respectively connected to different ones of the plurality of semiconductor chips.

9. The semiconductor device according to claim 2,
wherein the semiconductor chip is a vertical semiconductor chip that includes, on the front surface thereof, a front surface main electrode and a control electrode, and, on a rear surface thereof, a rear surface main electrode that is connected to the one wiring pattern,
wherein the metal wiring includes first metal wiring electrically connected to the control electrode and second metal wiring electrically connected to the rear surface main electrode, the first metal wiring and the second metal wiring each having a part that is not covered by and is exposed from the insulating encapsulating member, and
wherein the semiconductor device further comprises an insulating member that covers at least part of at least one of the part of the first metal wiring exposed from the insulating encapsulating member or the part of the second metal wiring that is exposed from the insulating encapsulating member.

10. The semiconductor device according to claim 2,
wherein the semiconductor chip is a vertical semiconductor chip, and has, on a front surface thereof, a front surface main electrode, and, on a rear surface thereof, a rear surface main electrode that is connected to the one wiring pattern,
wherein the metal wiring includes a first metal wiring electrically connected to the front surface main element electrode and a second metal wiring electrically connected to the rear surface main electrode, the first metal wiring and the second metal wiring each having a part that is not covered by and is exposed from the insulating encapsulating member,
wherein the semiconductor device further comprises an insulating member that covers at least part of at least one of the part of the first metal wire that is exposed from the insulating encapsulating member or the part of the second metal wire that is exposed from the insulating encapsulating member.

11. The semiconductor device according to claim 1, wherein the semiconductor device has a current rating of 100 A or higher and a voltage rating of 1700 V or higher.

12. The semiconductor device according to claim 1, wherein the thickness of the insulating encapsulating member from the upper surface of the insulating substrate is 3 mm or less.

13. A semiconductor device, comprising:
an insulating substrate having a plurality of wiring patterns thereon;
a semiconductor chip disposed on one wiring pattern among the plurality of wiring patterns;
metal wiring that is electrically connected to the semiconductor chip;
a case having a bottom at which the insulating substrate is disposed;
an insulating encapsulating member that fills in the case so as to cover the semiconductor chip from an upper surface of the insulating substrate; and
an insulating member that covers a portion of the semiconductor device that is to be insulated and is exposed from the insulating encapsulating member, wherein
the semiconductor device has a current rating of 100 A or higher and a voltage rating of 1700 V or higher, and a thickness of the insulating encapsulating member from the upper surface of the insulating substrate in a direction orthogonal to a surface of the insulating substrate is 3 mm or less.

14. A method of manufacturing a semiconductor device, comprising:
in a case having a bottom at which an insulating substrate is disposed, the insulating substrate having a plurality of wiring patterns disposed thereon, filling in the case with an insulating encapsulating member to a predetermined thickness on an upper surface of the insulating substrate in a direction orthogonal to a surface of the insulating substrate sufficient to cover a semiconductor chip disposed on one wiring pattern among the plurality of wiring patterns while leaving exposed at least part of metal wiring electrically connected to the semiconductor chip.

15. The method of manufacturing a semiconductor device according to claim 14, wherein the insulating encapsulating member is a gel.

16. The method of manufacturing a semiconductor device according to claim 15, further comprising covering a predetermined portion of the semiconductor device that is exposed from the insulating encapsulating member and is to be insulated with an insulating member.

17. The method of manufacturing a semiconductor device according to claim 16, wherein the covering the predetermined portion with the insulating member is performed before the filling in the case with the insulating encapsulating member.

18. The method of manufacturing a semiconductor device according to claim 16, wherein the filling in the case with the insulating encapsulating member includes:
injecting the insulating encapsulating member into the case to have a thickness greater than the predetermined thickness;
after the predetermined portion has been covered with the insulating encapsulating member, drawing out the insulating encapsulating member until a thickness of the insulating encapsulating member is decreased to the predetermined thickness and the predetermined portion is exposed from the insulating encapsulating member; and
thereafter performing the covering the predetermined portion with insulating encapsulating member.

19. The method of manufacturing a semiconductor device according to claim 16, wherein the filling in the case with the insulating encapsulating member includes:
discharging the insulating encapsulating member onto the predetermined portion until the insulating encapsulating member reaches the predetermined thickness; and
stopping the discharging when the insulating encapsulating member has reached the predetermined thickness, and
thereafter performing the covering the predetermined portion with insulating encapsulating member.

20. The method of manufacturing a semiconductor device according to claim 16, wherein the insulating member is an adhesive or a resin.

21. The method of manufacturing a semiconductor device according to claim 14, wherein the predetermined thickness is 3 mm or less.
